(19) United States
(12) Patent Application Publication
(10) Pub. No.: US 2023/0371403 A1
(43) Pub. Date: Nov. 16, 2023

(54) SUPERCONDUCTING MATERIALS AND METHODS OF MAKING THE SAME

(71) Applicants: University of Rochester, Rochester, NY (US); THE BOARD OF REGENTS OF THE NEVADA SYSTEM OF HIGHER EDUCATION ON BEHALF OF THE UNIVERSITY OF NEVADA,, Las Vegas, NV (US)

(72) Inventors: Liyanagamage R. Dias, Rochester, NY (US); Ashkan Salamat, Las Vegas, NV (US)

(73) Assignees: University of Rochester, Rochester, NY (US); THE BOARD OF REGENTS OF THE NEVADA SYSTEM OF HIGHER EDUCATION ON BEHALF OF THE UNIVERSITY OF NEVADA,, Las Vegas, NV (US)

(21) Appl. No.: 18/018,542

(22) PCT Filed: Jul. 29, 2021
(86) PCT No.: PCT/US2021/043785

§ 371 Date: Jan. 27, 2023

Related U.S. Application Data
(60) Provisional application No. 63/058,324, filed on Jul. 29, 2020.

(51) Int. Cl. H10N 60/85; H10N 60/01

(52) U.S. Cl. CPC H10N 60/85; H10N 60/01

(57) ABSTRACT

Superconductive materials and methods of making the same are described, in which the superconductive materials are grown on a crystalline substrate having lattice parameters that impart a strain on the superconductive materials that reduces an applied pressure at which the superconductive materials exhibit superconductivity.

### CROSS-REFERENCE TO RELATED APPLICATIONS

This application claims the benefit of U.S. Provisional Application No. 63/058,324 filed on Jul. 29, 2020. It also has some subject matter relationship to International Application Number PCT/US21/42447, filed on Jul. 20, 2021. To the extent permitted in applicable jurisdictions, the entire contents of these applications are incorporated herein by reference, as are all publications cited below.

### BACKGROUND

The present disclosure relates to superconducting materials and methods of making superconducting materials using molecular-beam epitaxy (MBE).

Superconductivity has been known for over 100 years. However, materials developed to date do not exhibit superconductivity at ambient conditions that are sufficiently close to those necessary for many practical applications. Developing materials that can exhibit superconductivity at commercially viable temperature and pressure conditions is necessary to leverage the significant potential benefits of superconductivity on a larger scale.

### SUMMARY

The search, synthesis, and structural and physical characterization of novel metal superhydrides with high superconducting transition temperature needed for observation of room temperature superconductivity (RTSC), and an understanding of how to access metastable pathways to their recovery to ambient conditions, is critical for the advancement of material science and energy transmission technology. Limitations with the energy storage produced from renewable energy technologies may be overcome with superconductors providing an extremely efficient means of storing and recovering energy on demand, as well as a method for transferring energy over long distances. A robust superconductor, suitable for the construction of Josephson junction quantum logic gates that can operate at higher temperatures has the potential to provide a revolutionary new switching mechanism for computing.

Moreover, many of today's quantum systems (e.g., involving qubits, superconducting materials, topological systems, etc.) can be difficult to reliably interface with classical (e.g., non-quantum) systems, in part due to steep thermal transitions. In this regard, the scalability of these complex systems can be severely limited by the challenges of managing their heat loads under cryogenic operating temperatures. Reliable non-cryogenic or even room-temperature quantum components will help overcome many of these difficulties, and these materials will be integral to quantum computing systems (e.g., to permit the coherent manipulation of electrons in spin-based quantum computers).

While higher temperature conventional superconductivity in hydrogen-rich materials has been reported in several systems under high pressure (see, Drozdov, A. P., Eremets, M. I., Troyan, I. A., Ksenofontov, V. & Shylin, S. I. Conventional superconductivity at 203 kelvin at high pressures in the sulfur hydride system, Nature 525, 73-76 (2015) (“Drozdov 1”); Drozdov, A. P. et al. Superconductivity at 250 K in lanthanum hydride under high pressures, Nature 569, 528-531 (2019) (“Drozdov 2”); and Somayazulu, M. et al. Evidence for Superconductivity above 260 K in Lanthanum Superhydride at Megabar Pressures, Phys. Rev. Lett. 122, 27001 (2019).[4] Bi, T., Zarifi, N., Terpstra, T. & Zurek, E. The Search for Superconductivity in High Pressure Hydrides, in Reference Module in Chemistry, Molecular Sciences and Chemical Engineering (Elsevier, 2019), doi:10.1016/B978-0-12-409547-2.11435-0), these materials do not exhibit superconductivity at a combination of pressures and temperatures needed for most commercial applications. The present disclosure addresses this need.

Superconducting structures and methods of manufacturing the same are provided herein.

In some aspects, the present disclosure provides methods comprising providing a crystalline substrate including a growth surface having a set of lattice parameters; and growing, on the growth surface, a solid hydride material, wherein the set of lattice parameters impart a strain to the solid hydride material that reduces an applied pressure at which the solid hydride material exhibits superconductivity.

In another aspect, the present disclosure provides a superconducting structure, comprising: a crystalline substrate including a growth surface having a set of lattice parameters; and a solid hydride material formed over the crystalline substrate, wherein the set of lattice parameters of the crystalline substrate impart a strain to the solid hydride material that reduces an applied pressure at which the solid hydride material exhibits superconductivity.

In some embodiments, the solid hydride material comprises a metallic crystal including a metal or carbon, sulfur, and hydrogen. In some embodiments, providing the crystalline substrate comprises growing a diamond structure by chemical vapor deposition. In one embodiment, the growth surface is parallel to a (110) lattice plane or a (121) lattice plane of the diamond structure (note that “(110)” and “(121)” denote Miller indices for the lattice planes).

In some embodiments, providing the crystalline substrate further comprises replacing carbon atoms of the grown diamond structure by substitutional doping with boron (B), sulfur (S), phosphorus (P), hydrogen sulfide (H₂S), or a combination thereof. In some embodiments, the substitutional doping comprises focused ion beam deposition of B, S, P, H₂S, or a combination thereof.

In some embodiments, growing the solid hydride material comprises depositing, via molecular-beam epitaxy, constituents thereof.

In another embodiment, the solid hydride material comprises a host-guest structure. In some embodiments, a guest component of the host-guest structure includes a sulfur hydride, a carbon hydride, or a combination thereof. In some embodiments, a host component of the host-guest structure includes Li, B, Be, Mg, Mn, Fe, Sc, N, Se, P, Y, C, S, La, or a combination thereof.

In some embodiments, the solid hydride material exhibits superconductivity, absent the strain, at a first combination of a first temperature and a first pressure. In another embodiment, the solid hydride material exhibits superconductivity, due to the strain, at a second combination of a second temperature and a second pressure, wherein the second temperature is higher than the first temperature, the second pressure is lower than the first pressure, or both.

In some embodiments, the solid hydride material has an Im-3 m cubic or Cmcm orthorhombic crystal structure. In some embodiments, the set of lattice parameters of the growth surface are symmetrical with the crystal structure of the solid hydride material.

In some embodiments, the strain reduces an inter-atomic spacing in the solid hydride material. In some embodiments, the inter-atomic spacing is an inter-hydrogen spacing. In some embodiments, the inter-hydrogen spacing is between 1.1 and 1.3 Å.

In some embodiments, the solid hydride material comprises a component covalently bonded to hydrogen and having a coordination number of at least 6. In some embodiments, the solid hydride material comprises a covalent metal hydride. In another embodiment, the solid hydride material has a hydrogen content that is higher compared to a largest content possible as determined by formal oxidation states of constituent elements of the solid at ambient conditions absent the strain.

### BRIEF DESCRIPTION OF THE DRAWINGS

FIG. 1 is a representative schematic of a superconducting structure comprising a solid hydride material and a crystalline substrate according to an embodiment of the present disclosure.

FIG. 2 is a representative schematic illustrating crystal lattice mismatch-induced strain between a solid hydride material and a substrate according to an embodiment of the present disclosure.

FIG. 3 is a representative schematic of an MBE chamber with effusion cells for different species used in making the solid hydride material according to an embodiment of the present disclosure.

FIG. 4 is a crystal structure of an exemplary solid hydride material according to an embodiment of the present disclosure.

FIG. 5 is a flow chart illustrating a method for making a superconducting material according to an embodiment of the present disclosure.

### DETAILED DESCRIPTION

While the present disclosure is capable of being embodied in various forms, the description below of several embodiments is made with the understanding that the present disclosure is to be considered as an exemplification of the invention and is not intended to limit the invention to the specific embodiments illustrated.

The use of numerical values in the various quantitative values specified in this application, unless expressly indicated otherwise, are stated as approximations as though the minimum and maximum values within the stated ranges were both preceded by the word “about.” It is to be understood, although not always explicitly stated, that all numerical designations are preceded by the term “about.” It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth. Also, the disclosure of ranges is intended as a continuous range including every value between the minimum and maximum values recited as well as any ranges that can be formed by such values.

One of the long-standing challenges in experimental physics is the observation of room-temperature superconductivity (RTSC). In the past decade there has been a renaissance in materials discovery towards room-temperature superconductivity, for which extreme pressure has proved to be the most versatile order parameter as it facilitates the production of new quantum materials with unique stoichiometries and a mechanism for pressure induced metallization. See, Bi, T., Zarifi, N., Terpstra, T. & Zurek, E. The Search for Superconductivity in High Pressure Hydrides, in Reference Module in Chemistry, Molecular Sciences and Chemical Engineering (Elsevier, 2019) doi: 10.1016/B978-0-12-409547-2.11435-0; Pickard, C. J., Errea, I. & Eremets, M. I. Superconducting Hydrides Under Pressure, Annu. Rev. Condens. Matter Phys. 11, 57-76 (2020)).

One of the most significant discoveries in reaching RTSC is the pressure-driven disproportionation of hydrogen sulfide (H₂S) to H₃S with a confirmed T_{c} of 203 kelvin at 155 gigapascals. (Drozdov 1). The syntheses of superhydrides at reduced pressures (e.g., significantly lower than 155 gigapascals) would enable transformative technologies ranging from energy transportation to quantum computing.

Provided herein are superconducting materials (e.g. superhydrides) and methods of making the same, that can achieve superconductivity at commercially relevant pressures and temperatures. The methods and materials can exploit epitaxial strain from a lattice mismatch between a solid hydride material and a corresponding crystalline substrate on which they are formed to reduce the pressure (e.g., applied mechanically via a diamond anvil cell (DAC) or the like) at which one or both of the materials exhibit superconductivity.

In some embodiments, the methods comprise providing a crystalline substrate including a growth surface, the growth surface having a set of lattice parameters (e.g., the lattice constants in one, two, or three dimensions and the lattice vectors that define the angles therebetween). In some embodiments, the set of lattice parameters of the growth surface are symmetrical with the crystal structure of the solid hydride material. The crystalline substrates are designed to be slightly frustrated lattices (e.g., with the same or similar space group and symmetry of the grown superconducting material). For example, if the desired final space group for the superconducting material is Im-3 m or Cmcm, the substrate would have the same space group but with lattice parameters (e.g., one or more lattice constants) different than that of the superconducting material. The difference in the lattice parameters between the substrate and the superconducting material creates a chemical pressure that reduces an inter-atomic (e.g., inter-hydrogen) spacing in the superconducting material, and therefore reduces the pressure at which the superconducting material exhibits superconductivity.

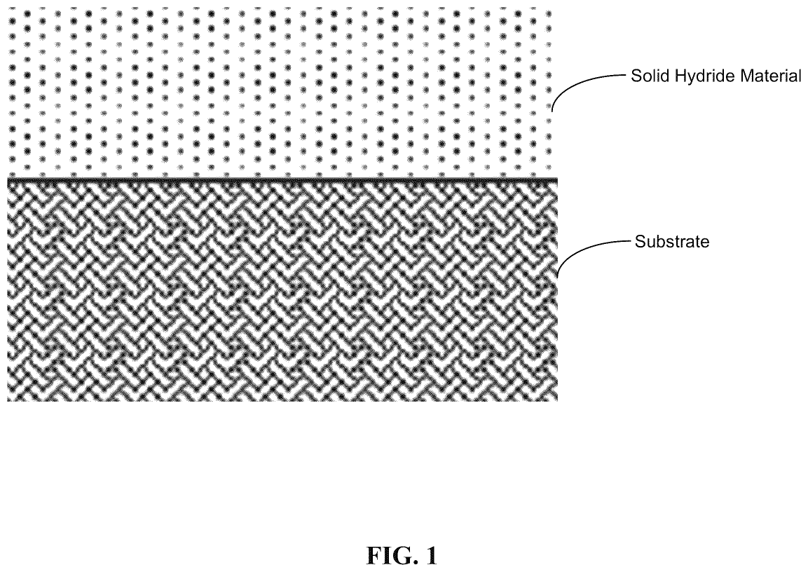

In some embodiments, the methods further comprise growing, on the growth surface of the substrate, a solid hydride material (e.g., a host-guest material, inclusion compound, or clathrate compound). FIG. 1 depicts one such host-guest structure grown on the substrate surface in accordance with an embodiment of the present disclosure. In some embodiments, the set of lattice parameters of the substrate are selected by chemically tuning the substrate (e.g., with substitutional or interstitial doping) to impart a strain to the solid hydride material that reduces an applied pressure (e.g., mechanical pressure) at which the solid hydride material exhibits superconductivity.

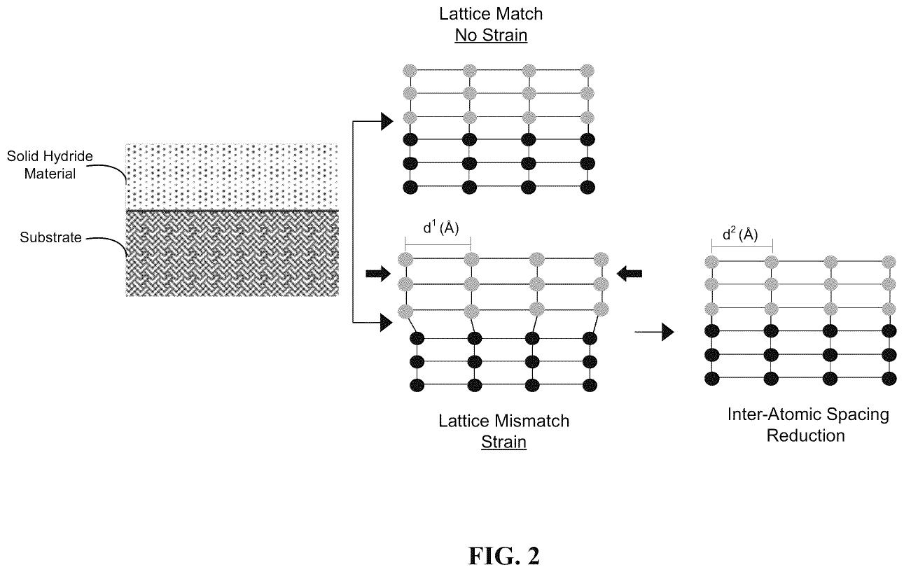

In accordance with one aspect of the present disclosure, the strain imparted to the grown solid hydride material arises from a mismatch in the lattice parameters of the solid hydride material and the crystalline substrate, as depicted in FIG. 2. As can be seen with reference to FIG. 2, when the lattice of the solid hydride material and the substrate match, there is no strain and the inter-atomic spacing of the solid hydride material is unchanged. However, when there is a lattice mismatch between the solid hydride material and the substrate, the mismatch generates strain that reduces an inter-atomic spacing of components (e.g., hydrogen) of the solid hydride material.

In some embodiments, the desired final space group for the superconducting materials may be Im-3 m or Cmcm. Accordingly, in some embodiments, the crystal system of the superconducting material is orthorhombic (e.g., in which the set of lattice parameters includes three unique lattice constants in each of three mutually-orthogonal directions) or cubic (e.g., in which the set of lattice parameters includes a single uniform lattice constant in each of three mutually-orthogonal directions). In other embodiments, the desired final space group for the superconducting materials may be any one of Fm3̅m̅, Fd3̅m̅, Pnma, P2₁/c, or P1. The foregoing space groups are but examples of some of the possible space groups of which the substrate and/or the solid hydride material may be members, as will be readily understood by one of skill in the art, and are not intended to be an exhaustive list. Rather, the substrate and/or the solid hydride material may each be any one of the 230 known space groups, without restriction.

In some embodiments, the lattice mismatch between the solid hydride material and the substrate may be in the range of about 1% to about 20%. For example, the lattice mismatch between the solid hydride material and the substrate is about 1%, about 5%, about 10%, about 15%, or about 20%. In accordance with various aspects of the present disclosure, the lattice mismatch may comprise a mismatch between any of the three lattice constants a, b, or c, any of the three lattice vectors α, β, or γ, or any combination thereof. As will be readily understood by those of skill in the art, a greater lattice mismatch between the substrate and the solid hydride material can impart a greater degree of strain, and therefore provide a greater reduction in inter-atomic spacing of the solid hydride material grown on the substrate. Of course, as will likewise be readily understood by those of skill in the art, too great a lattice mismatch can increase the difficulty of forming one lattice upon another, such that degree of lattice mismatch selected represents a compromise between increased strain in the solid hydride material (and accordingly a lower applied pressure at which it exhibits superconductivity) and increased difficulty of manufacture. Moreover, depending upon the material of the solid hydride, the change in inter-atomic spacing may not scale linearly with the lattice mismatch, such that too great a lattice mismatch may begin to increase, rather than continue to decrease, the inter-atomic spacing of the solid hydride material. Accordingly, the optimization of the lattice mismatch is material-dependent, as will be readily understood by those of skill in the art.

In addition to or in alternative to a mismatch of lattice parameters, in some embodiments the lattice mismatch between the solid hydride material and the substrate may be provided by a mismatch of the space groups of the substrate and the solid hydride material, by a mismatch of symmetry operators therebetween, or a combination thereof. Moreover, in addition to or in alternative to a mismatch of lattice parameters, space groups, and symmetry operators, in some embodiments the lattice mismatch between the solid hydride material and the substrate may be provided by a rotational misalignment between the lattices of the substrate and the solid hydride material. For example, the lattices of the substrate and the solid hydride material may be rotated with reference to one another by an amount in the range of about 1° to about 20°. Without wishing to be bound by theory, it is believed that this rotational misalignment provides a torque-type strain that can reduce an inter-atomic (e.g., inter-hydrogen) spacing in the solid hydride material.

In some embodiments, the solid hydride material and the substrate each have a space group of Im-3 m and a lattice mismatch of about 1% to about 20%. For example, the lattice mismatch between the solid hydride material and the substrate is about 1%, about 5%, about 10%, about 15%, or about 20%. In other embodiments, the solid hydride material and the substrate each have a space group of Cmcm and a lattice mismatch of about 1% to about 20%. For example, the lattice mismatch between the solid hydride material and the substrate is about 1%, about 5%, about 10%, about 15%, or about 20%.

In some embodiments, the solid hydride material and the crystalline substrate have different lattice constants. In these embodiments, the lattice constants of the solid hydride material and the crystalline substrate can differ by about 1% to about 20%. For example, in some embodiments, the lattice constants of the crystalline substrate may be less than the lattice constants of the solid hydride material, generating a compressive strain in the solid hydride material. In these embodiments, the lattice mismatch can generate a compressive lattice mismatch strain that can reduce one or more lattice constants of the solid hydride material by between about 1% to about 35% (e.g., by an amount about equal to the difference in lattice constants plus or minus 15%). By way of further example, in other embodiments, the lattice constants of the crystalline substrate may be greater than the lattice constants of the solid hydride material, generating a tensile strain in the solid hydride material. In these embodiments, the lattice mismatch can generate a tensile lattice mismatch strain that can increase one or more lattice constants of the solid hydride material by between about 1% to about 35% (e.g., by an amount about equal to the difference in lattice constants plus or minus 15%).

In some embodiments, the lattice mismatch can impart sufficient strain to the solid hydride material to reduce an inter-atomic (e.g., inter-hydrogen) spacing in the solid hydride material, and therefore reduce the pressure at which the superconducting material exhibits superconductivity. For example, in some embodiments, a difference in lattice parameters of up to about 20% can cause a reduction in inter-atomic spacing in the solid hydride material of up to 80% (e.g., about 80%, about 60%, about 50%, about 40%, about 30%, about 20%, or about 10%). As will be readily understood by those of skill in the art, the relationship between lattice-mismatch strain and compression is not linear relationship, but rather described by a polynomial function.

In some embodiments, the lattice mismatch can impart sufficient strain to the solid hydride material to permit it to exhibit superconductivity at a pressure below 180 gigapascals (GPa). For example, in some embodiments, the lattice mismatch can impart sufficient strain to the solid hydride material to permit it to exhibit superconductivity at a pressure below about 180 GPa, below about 150 GPa, below about 100 GPa, below about 75 GPa, below about 50 GPa. In some embodiments, the lattice mismatch can impart sufficient strain to the solid hydride material to permit it to exhibit superconductivity below about 30 GPa (e.g., a pressure below about which superconducting devices can be provided outside of the laboratory environment), below about 10 GPa (e.g., a pressure below about which superconducting devices can be provided at commercially viable levels of cost and complexity), below about 2 GPa (e.g., a pressure below about which superconducting devices can be cost-effectively provided at very large scales), at or below about atmospheric pressure, or even in vacuum environments.

In some embodiments, pressure can be applied to the solid hydride material via mechanical pressure. For example, the superconducting material can be loaded into a DAC and compressed between facing culets. In some embodiments, a pressure-transmitting medium (e.g., argon, xenon, hydrogen, helium, methanol, ethanol, paraffin oil, etc., or some combination thereof) can be included within the diamond anvil cell to convert the uniaxial pressure supplied by the DAC into uniform hydrostatic pressure. As will be readily appreciated by those of skill in the art, lower operating pressures permit the use of a DAC with a larger sample size, such that when a lattice mismatch can impart sufficient strain to permit the solid hydride material to exhibit superconductivity at a lower pressure, larger devices including the superconducting material, such as millimeter- or even centimeter-scale quantum processors, can be operated in a DAC. In other embodiments, other devices for applying mechanical pressure, including other anvil presses comprising less expensive anvil materials than diamond (e.g., metals), may also be used.

In some embodiments, the solid hydride material exhibits superconductivity at increased temperatures above about 150 kelvin (K). For example, in some embodiments, the solid hydride material exhibits superconductivity at an increased temperature of about 150 K, about 175 K, about 200 K, about 225 K, about 250 K, about 260 K, about 270 K, or about 280 K.

In some embodiments, the solid hydride material exhibits superconductivity at a reduced pressure and an increased temperature. In some embodiments, the solid hydride material exhibits superconductivity at ambient pressure and temperature. In some embodiments, the solid hydride material exhibits superconductivity at a reduced pressure and increased temperature, wherein the reduced pressure is below about 180 GPa and the increased temperature is above about 260 K.

In some embodiments, the solid hydride material is a host-guest structure including a guest component and a host component. In some embodiments, the guest component includes a sulfur hydride, a carbon hydride, or a combination thereof. In some embodiments, the host component includes lithium (Li), boron (B), beryllium (Be), or combination thereof. Without wishing to be bound by theory, it is believed that the presence of Li, B, Be, lighter atoms, assists with electron phonon coupling mechanisms and phono-mediated superconductivity. In some embodiments, the host component includes magnesium (Mg), manganese (Mn), iron (Fe), scandium (Sc), yttrium (Y), or a combination thereof. Without wishing to be bound by theory, it is believed that the presence of Mg, Mn, Fe, Sc, and Y permits a greater amount of hydrogen intercalated into the host-guest structures at relatively lower pressures. In some embodiments, the host component includes nitrogen (N), selenium (Se), phosphorous (P), or a combination thereof. Without wishing to be bound by theory, it is believed that the presence of N, Se, and P makes available lone pairs for donating into the sigma* bonds of H₂ to drive bond dissociation (a lowering of the bond order). In some embodiments, the host component includes Li, B, Be, Mg, Mn, Fe, Sc, N, Se, P, Y, C, S, La, or any combination thereof. In some embodiments, the superconducting material may be a clathrate compound or an inclusion compound comprising a lattice or framework of hydrogen-containing materials and one or more guest components, including Li, B, Be, Mg, Mn, Fe, Sc, N, Se, P, Y, C, S, La, or any combination thereof.

In some embodiments, the methods comprise providing the crystalline substrate by growing a diamond structure by chemical vapor deposition. The different crystallographic orientations of diamond permit access to a range of lattice parameters for use as a substrate. In an embodiment in which undoped diamond crystal is used as the substrate, the lattice parameters may be a=b=c=3.567 Å and α=β=γ=90°. For embodiments in which a diamond crystal is doped to tune the lattice parameters thereof, the lattice constants may be between about 3 Å and 5 Å. In other embodiments using crystal substrates, the lattice constants (for the primitive cell) may be between about 2.5 Å and about 10 Å. In some embodiments, the growth surface is parallel to a (110) lattice plane of the diamond structure. In other embodiments, the growth surface is parallel to a (121) lattice plane of the diamond structure.

In some embodiments, the method further comprises replacing carbon atoms within the diamond structure with other materials (e.g., atoms of other elements or with other molecules) via substitutional doping to provide the substrate with desired lattice parameters and/or to provide additional sources of hydrogen to the superconducting material. In some embodiments, the other materials include boron (B), sulfur (S), phosphorus (P), Hydrogen Sulfide (H₂S), or a combination thereof. In some embodiments, replacing the carbon atoms comprises focused ion beam deposition of B, S, P, H₂S, or a combination thereof.

In some embodiments, the method further comprises tuning lattice parameters of the diamond structure with interstitial dopants (e.g., atoms of elements other than carbon or other molecules). In some embodiments, the other materials include hydrogen (H), fluorine (F), chlorine (CI), bromine (Br), iodine (I), astatine (At), silicon (Si), germanium (Ge), tin (Sn), lead (Pb), Flerovium (Fl), or any combination thereof. In some embodiments, interstitial doping the other materials into the diamond structure comprises focused ion beam deposition.

In some embodiments, substitutional doping to replace carbon atoms within the diamond structure with other materials permits fine tuning of the lattice parameters at the growth surface of the substrate. For example, substitutional doping with materials larger than carbon, such as sulfur, phosphorus, or the like, can increase one or more of the lattice constants at the growth surface, while substitutional doping with materials smaller than carbon, such as boron, can decrease one or more of the lattice constants at the growth surface. In some embodiments, interstitial doping can further fine tune the lattice parameters at the growth surface of the substrate (e.g., either by increasing or decreasing one or more lattice constants at the growth surface).

In some embodiments, the method further comprises tuning lattice parameters of the diamond structure with vacancies. For example, bombarding the crystal structure with carbon atoms can dislodge other carbon atoms from their position within the crystal lattice and leave a vacancy at the site, thereby reducing one or more lattice constants in the area of the vacancy. As will be readily understood by those of skill in the art, other methods of introducing vacancies in a crystal lattice, whether of carbon or any other material, may also be used to tune the lattice parameters.

In some embodiments, the amount of vacancies, or substitutional or interstitial dopants, may be selected to provide desired lattice parameters at the growth surface. In this regard, the amount of dopants may be a low level (e.g., on the order of one dopant for every 1,000,000 to 100,000,000 carbon atoms), a high level of doping (e.g., on the order of one dopant for every 10,000 to 1,000,000 carbon atoms), or a very high level of doping (e.g., more than one dopant for every 10,000 carbon atoms).

In some embodiments, the dopants may be provided at the growth surface (e.g., in the portion of the crystal lattice adjacent to the grown solid hydride material). In other embodiments, the dopant may extend to a deeper level in the crystal lattice, or even through the bulk of the substrate material. In some embodiments, the dopant concentration may be constant, while in other embodiments the dopant concentration may vary according to distance from the growth surface (e.g., providing a lattice constant varying with depth).

In some embodiments, the growth surface may be patterned or textured (e.g., using known lithography techniques) to encourage the growth of the solid hydride material in a desired orientation, to improve the regularity of the solid hydride material crystal lattice, or otherwise promote desired properties in the grown solid hydride material.

Although in the foregoing example embodiment, the substrate is described and illustrated as a diamond crystal structure grown by CVD and optionally doped by focused ion beam deposition, in other embodiments other substrate materials formed by different processes can also be used. For example, in some embodiments, other substrates such as graphene, graphane, silicon, silicon derivatives, or any combination thereof can be used in place of diamond to provide access to a variety of tunable lattice parameters via doping that would permit the fabrication of solid hydrides that exhibit superconductivity at desired combinations of temperature and pressure. Moreover, binary crystals, such as silicon carbide, can be used as a substrate and may, in some embodiments, be provided by substituting a significant fraction (e.g., a quarter, a third, half, two thirds, three quarters, etc.) of the carbon atoms in a diamond crystal structure with focused ion beam deposition, as set forth in greater detail above. In accordance with some embodiments, diamond and other crystals may be formed by processes other than CVD (e.g., by large volume pressure for high pressure-temperature synthesis, by crystal melt methods, by the Czochralski method, by various lamination processes, the ‘scotch-tape method,’ atomic layer deposition (ALD), physical vapor deposition (PVD), sputtering, or any combination thereof). In accordance with some embodiments, substitutional and interstitial doping of diamond and other crystals may be performed by processes other than focused ion beam deposition (e.g., by PVD, MBE, bore milling, various reaction chemistry methods including laser heating methods, large volume press methods, etc., or any combination thereof).

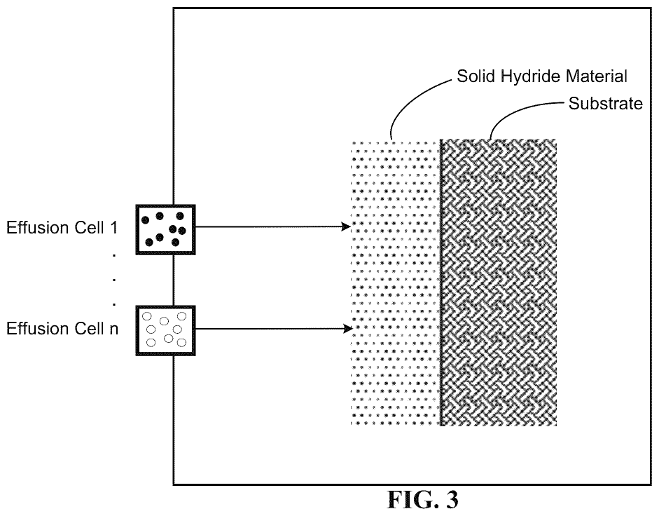

In some embodiments, growing the solid hydride material comprises separately depositing, via MBE, the constituents thereof. FIG. 3 depicts an exemplary MBE chamber in which the constituents of the solid hydride material are present in Effusion Cells 1-n. The constituents of the solid hydride material are vaporized in the effusion cells and directed towards desired locations on the growth surface of the substrate, where the solid hydride material is grown. In some embodiments, additional effusion cells containing the doping species used to replace the carbon atoms within, or add interstitial dopants to, the diamond structure may also be used.

In some embodiments, growing the solid hydride material by MBE can involve directing constituents of the solid hydride material into desired locations on the growth surface based on the desired crystal structure of the solid hydride material. For example, to fabricate a two-dimensional or three-dimensional crystal structure by MBE, specific site locations in a growing crystal lattice can be singly populated with materials (e.g., a single atom or a single molecule) emitted by effusion cells, in a manner analogous to known nanoassembly methods. In some embodiments, a three-dimensional crystal lattice can be built up of multiple stacked two-dimensional crystal layers. (See, Wofford, J., Nakhaie, S., Krause, T. et al., A hybrid MBE-based growth method for large-area synthesis of stacked hexagonal boron nitride/graphene heterostructures, Sci Rep 7, 43644 (2017), doi:10.1038/srep43644) (“Wofford”). In such embodiments, although deposition may occur layer-by-layer, interlayer interactions between heterogenous layers can provide a mechanism for three-dimensional nanoassembly. (See, Xiang Yuan, Lei Tang, Shanshan Liu, Peng Wang, Zhigang Chen, Cheng Zhang, Yanwen Liu, Weiyi Wang, Yichao Zou, Cong Liu, Nan Guo, Jin Zou, Peng Zhou, Weida Hu, & Faxian Xiu, Arrayed van der Waals Vertical Heterostructures Based on 2D GaSe Grown by Molecular Beam Epitaxy, Nano Lett. 2015, 15 (5) 3571-3577, doi:/10.1021/acs.nanolett.5b01058; Bongjoong Kim, Jiyeon Jeon, Yue Zhang, Dae Seung Wie, Jehwan Hwang, Sang Jun Lee, Dennis E. Walker Jr., Don C. Abeysinghe, Augustine Urbas, Baoxing Xu, Zahyun Ku, & Chi Hwan Lee, Deterministic Nanoassembly of Quasi-Three-Dimensional Plasmonic Nanoarrays with Arbitrary Substrate Materials and Structures, Nano Letters 2019 19 (8), 5796-5805, doi:10.1021/acs.nanolett.9b02598.)

Alternatively, or in addition, one or more three-dimensional islands can form a site around which three-dimensional crystals can be built. In some embodiments, the foregoing nanoassembly methods can be used to provide a 3D electronic band structure (e.g., in a periodic network or between deposited layers). In some embodiments, the multiple stacked two-dimensional crystal layers are bonded through van der Waals interactions, forming van der Waals heterostructures of the solid hydride material. In these and other embodiments, reflection high-energy electron diffraction (RHEED) may be used to monitor the growth of the crystal layers.

In some embodiments, the methods further comprise using MBE to initiate a reaction between two or more different materials (having one or more constituent elements) and hydrogen so as to form a plurality of molecules each comprising a hydrogen moiety and at least one of the constituent elements from a different one of the materials. In an example with two different molecules, the plurality of molecules comprises a first molecule having a first composition and a second molecule comprising a second composition.

In some embodiments, the hydrogen of the solid hydride material may be provided in various forms or in various hydrogen precursors. Example hydrogen precursors include, but are not limited to, atomic hydrogen, molecular hydrogen, a hydrogen polymer, or a multi-valent hydride. More specific hydrogen precursors include, but are not limited to, methane, HS, Silane, LiH, or any hydrogen precursor (e.g., gaseous hydrogen precursor) used in molecular-beam epitaxy or chemical vapor deposition. In some embodiments, the solid hydride material has a hydrogen content that is higher compared to a largest content possible as determined by formal oxidation states of constituent elements of the solid at ambient conditions absent the strain.

Although in the various example embodiments described herein, reference is made to hydrogen, those of skill in the art will readily appreciate that any of the isotopes of hydrogen (e.g., protium, deuterium, or tritium) may be used in lieu of one another, in combination or alone. Accordingly, whenever reference is made to “hydrogen” herein, it is to be understood that any of these hydrogens are contemplated.

In some embodiments, the methods comprise selecting two or more different materials each including one or more constituent elements. Example constituent elements include, but are not limited selected from H, S, Li, B, Be, Mg, Mn, Fe, Sc, N, Se, P, Y, C, or La. Materials may be selected for their properties as stabilizing agents, pressurizing agents, or chemical dopants as described herein.

In some embodiments, the solid hydride material exhibits superconductivity, absent the strain, at a first combination of a first temperature and a first pressure. In some embodiments, the solid hydride material exhibits superconductivity, due to the strain, at a second combination of a second temperature and a second pressure, wherein the second temperature is higher than the first temperature, the second pressure is lower than the first pressure, or both.

In some embodiments, the solid hydride material comprises at least 3 different elements including hydrogen and exhibits superconductivity at a pressure of below about 180 GPa. In some embodiments, the host-guest structure is formed from a combination of compounds XHₓ+YH_{y}+H₂, where X is selected from Li, B, Be, Mg, Mn, Fe, Sc, N, Se, P, Y, C, S, and/or La and Y is selected from Li, B, Be, Mg, Mn, Fe, Sc, N, Se, P, Y, C, S, and/or La, and x and y are the stoichiometric amounts of the compounds comprising X and Y respectively. In some embodiments, the solid hydride material is a carbonaceous sulfur hydride.

In some embodiments, the solid hydride material comprises at least 4 different elements including hydrogen and exhibits superconductivity at a pressure below about 180 GPa. In some embodiments, the solid hydride material is formed form a combination of compounds XHₓ+YH_{y}+ZH_{z}+H₂, where X is selected from Li, B, Be, Mg, Mn, Fe, Sc, N, Se, P, Y, C, S, and/or La, Y is selected from Li, B, Be, Mg, Mn, Fe, Sc, N, Se, P, Y, C, S, and/or La, and Z is selected from Li, B, Be, Mg, Mn, Fe, Sc, N, Se, P, Y, C, S, and/or La, and x, y, and z are the stoichiometric or non-stoichiometric amounts of the compounds comprising X, Y, and Z, respectively.

In yet another embodiment, the solid hydride material comprises a first component A comprising a hydrogen-containing component comprising hydrogen; a second component B and a third component C; and the solid hydride has a formula AₐB_{b}C_{c}Hₓ; and wherein: b:c is in a range of 1:20 to 20:1, a:b is in the range of 1:20 to 20:1, x is in the range from 1 to 15, H is hydrogen, C may be H with x=0 in a ternary system and C is different from H in a quaternary system, and one or more of A, B, C are undoped or comprise a dopant concentration in a range from about 0% to 20%.

In some embodiments, the solid hydride material is a metallic crystal comprising a metal or carbon, sulfur, and the hydrogen. In yet another embodiment, the solid hydride material is a metallic crystal, or is formed from a composition, having the formula (H₂S)₂₋ₓ(CH₄)ₓH₂ or formed form a combination of compounds XHₓ+YH_{y}+ZH_{z}+H₂, where XHₓ is methane and YH_{y} is H₂S. In some embodiments, the solid hydride material comprises a component covalently bonded to hydrogen and having a coordination number of at least 6. In some embodiments, the solid hydride comprises a covalent metal hydride.

In yet another embodiment, the solid hydride material is a host-guest structure including a guest component and a host component, wherein the guest component includes hydrogen and the host component comprises at least one of: a stabilizing agent promoting bonding of the hydrogen to the host component and/or formation of a distinct network comprising at least some of the hydrogen; or a pressurizing agent applying chemical pressure to a periodic lattice of the host-guest structure so as to reduce inter-atomic spacing in the periodic lattice.

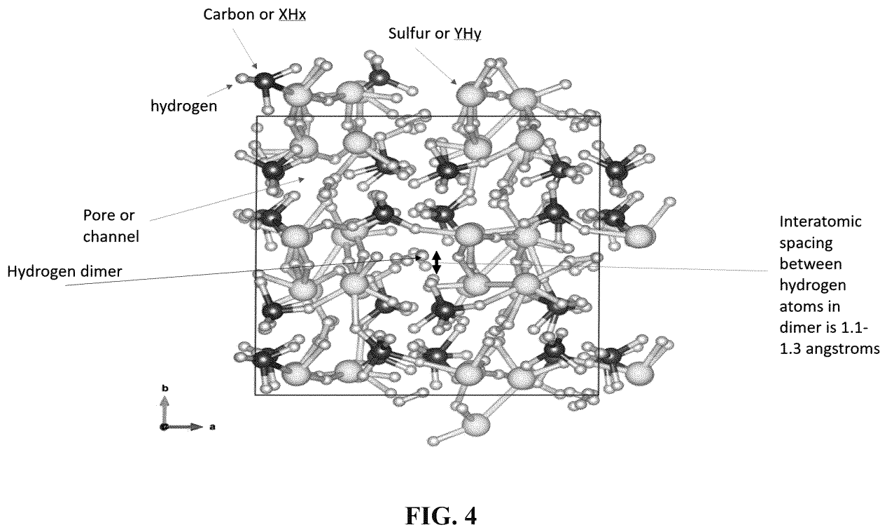

In some embodiments, the solid hydride material has reduced inter-atomic spacing between hydrogen atoms or dimers. FIG. 4 illustrates an example structure of the superconducting material manufactured according to the disclosed methods comprising carbon, hydrogen, and sulfur. The structure comprises the carbon and sulfur disposed with periodic stacking within a three-dimensional motif. In one or more embodiments, the sulfur is disposed in a Cmcm symmetrized motif and the overall structure is an Im-3 m structure.

In some embodiments, the sulfur and carbon may be substituted with different elements. In some embodiments, the structure includes a stabilizing agent (e.g., carbon, sulfur, or substitute for carbon or sulfur) promoting bonding of the hydrogen to surrounding lattice and/or formation of a distinct network comprising at least some of the hydrogen; or a pressurizing agent (e.g., carbon, sulfur, or substitute for carbon or sulfur) applying chemical pressure to the periodic lattice so as to reduce inter-atomic spacing in the lattice.

In some embodiments, the stabilizing agents comprise a chemical constituent (comprising a molecule or atom) including at least one of Li, B, Be, Mg, Mn, Fe, Sc, N, Se, P, Y, or La. Example pressurizing agents include a chemical constituent (e.g., atom or molecule) including at least one of Li, B, Be, Mg, Mn, Fe, Sc, Se, P, Y, or La. In various embodiments, the chemical constituent comprises both a stabilizing agent and pressurizing agent. Stabilizing agents and pressurizing agents may also be considered chemical dopants.

FIG. 4 further illustrates an example wherein the inter-atomic distance between the hydrogen atoms or dimers in the solid hydride material is in a range of 1.1-1.3 angstroms (e.g., similar to that found in metallic hydrogen). The hydrogen atoms can form molecular hydrogen (dimers or covalently bonded hydrogen pairs) in which the sigma bonds in the hydrogen are weakened as the bond order is lowered from 2 to possibly about 1.5. In other embodiments, the bond order may be reduced as low as zero so that the hydrogen atoms in the solid hydride material comprise atomic hydrogen. As used herein, bond order is the number of chemical bonds between a pair of atoms and indicates the stability of a bond. For example, in diatomic hydrogen (hydrogen dimer, H—H), the bond order is 2; in atomic hydrogen, the bond order is 0. The inter-atomic distance in the range of 1.1-1.3 angstroms may be the distance between hydrogen atoms in the dimer and/or between adjacent neighboring hydrogen atoms or hydrogen dimers.

In yet further embodiments, the hydrogen in the solid hydride material may be considered to comprise hydrogen atoms or dimers forming covalent bonds (e.g., directional bonds) with other neighboring hydrogen atoms or dimers as a consequence of the hydrogen atoms or dimers sharing electrons between them and overlapping or hybridization of two or more atomic orbitals. In yet further embodiments, the hydrogen atoms or hydrogen dimers interact with their neighbors in the solid hydride material through resonance bonding (e.g., similar to resonance bonding in benzene). In one or more embodiments, the hydrogen disposed in the solid hydride material comprises a self-interacting hydrogen rich network. In some embodiments, the solid hydride material comprises a framework defining channels, each of the channels comprising a series of hydrogen atoms or hydrogen dimers positioned along a length of the each of the channels.

FIG. 4 further illustrates an example host-guest structure that includes a host component and a guest component, wherein at least one of the host components or the guest component comprises a periodic lattice and the guest component includes hydrogen. The host component comprises at least one of the stabilizing agents promoting bonding of the hydrogen to the host component and/or formation of a distinct network comprising at least some of the hydrogen; or a pressurizing agent applying chemical pressure to the periodic lattice so as to reduce inter-atomic spacing in the lattice. In some embodiments, the methods comprise dissociating molecular hydrogen from the host-guest structure to enable inert atoms into the Van Der Waals-like printed lattice. In some embodiments, palladium (Pd) can enable the dissociating of the molecular hydrogen.

FIG. 4 further illustrates an example wherein the solid hydride material is a host-guest structure comprising a hydrogen network, hydrogen framework, or channels or pores comprising hydrogen. The channels or pores (e.g., 1-dimensional pores or 1-dimensional channels) comprise a series of hydrogen atoms or hydrogen dimers (molecular hydrogen) positioned along a length of the channels. In various embodiments, the distance between neighboring hydrogen atoms or dimers in the channel is in a range of 1.1 angstroms to 1.3 angstroms. In various embodiments, the channels or network comprise one or more fiber structures, one or more filament structures, or other structures whose length is substantially (e.g., at least 1000 times) longer than their width. The channels are defined by a surrounding lattice of chemical constituents (stabilizing agents and/or pressurizing agents) distinct from the hydrogen network. In various embodiments, the lattice, framework, or matrix (e.g., comprising chemical constituents such as the stabilizing agents or pressurizing agents) contains or holds the hydrogen and provides a chemical environment for the hydrogen allowing higher T_{C} at lower pressures. FIG. 4 illustrates an example wherein the stabilizing agent and/or pressurizing agent comprises chemical constituents including carbon and sulfur. However, other chemical constituents (e.g., stabilizing agents and pressurizing agents) may be used as illustrated herein.

In one or more embodiments, the superconductor comprises a solid hydride material including a first component A; a second component B and a third component C; and the solid hydride has the formula AₐB_{b}C_{c}Hₓ; wherein H is C in a ternary compound and C is different from H in a quaternary compound, b:c is in a range of 1:20 to 20:1, a:b is in a range of 1:20 to 20:1, x is in a range from 1 to 15, and A, B, or C are independently selected from Li, B, Be, Mg, Mn, Fe, Sc, N, Se, P, Y, C, S, or La. A, B, or C can be substituted with other elements from the list or other elements to reflect doping (e.g., doping with other elements up to 20%).

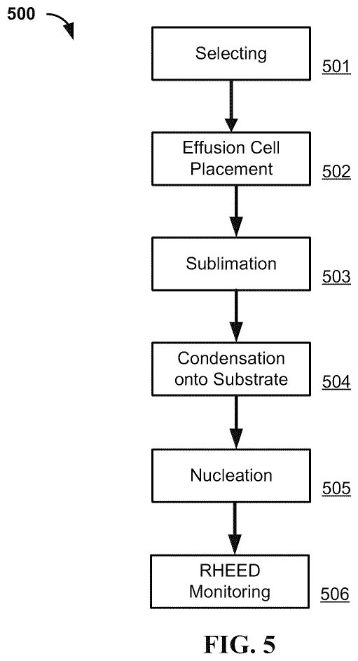

FIG. 5 is a flowchart illustrating a method 500 of making the superconducting, solid hydride material according to an embodiment of the present disclosure. The method 500 employs molecular beam epitaxy to deposit a crystalline film of the solid hydride material onto the crystalline substrate. The method 500 includes a step 501 of selecting the components for forming the solid hydride material. The selected components can either be in a gaseous or liquid phase. The components are then placed into separate effusion cells in step 502 within the MBE chamber. The MBE chamber is maintained at an ultra-high vacuum environment (e.g., <10⁻⁹ mbar). The effusion cells are equipped with mechanical shutters that allow for the control of the amount of each component used in forming the solid hydride material. Once in the effusion cells, the components in step 503 are sublimated from the solid form or evaporated from the liquid phase. In step 504, the gaseous components are then condensed onto the crystalline substrate, where they may react with each other. In some embodiments, to control the mobility of the gaseous components, the substrate is heated to high temperatures (e.g., 300° C.-600° C.). Once the gaseous components contact the substrate, there are numerous processes by which the components (i.e., adatoms) undergo growth to form the solid hydride material. Step 505 includes a nucleation process of the adatoms to initiate the crystal growth of the solid hydride material onto the substrate. The nucleation process 505 can take place on mono-atomic steps, on defects, or directly on the surface of the crystalline substrate. In an optional step 506, the method 500 includes monitoring the growth of the crystalline solid hydride layer using RHEED. In some embodiments, monitoring the crystal growth using RHEED includes generating a diffraction pattern of the crystal. RHEED allows monitoring the material deposition with sub-monolayer accuracy.

Further information relevant to one or more embodiments of the present invention can be found in the following publication (and online additional information): Snider, Elliot, Dasenbrock-Gammon, Nathan, McBride, Raymond, Debessai, Mathew, Vindana, Hiranya, Vencatasamy, Lawter, Kevin V., Salamat, Ashkan, and Dias, Ranga, Superconductivity in a Carbonaceous Sulfur Hydride, Nature, 586, 373-377 (14 Oct. 2020) and online additional information available at: doi.org/10.1038/s41586-020-2801-z. To the extent permitted in relevant jurisdictions, this article, and the associated additional information available online (and other publications cited herein) is hereby incorporated by reference in its entirety.

From the foregoing, it will be appreciated that specific embodiments of the invention have been described herein for purposes of illustration, but that various modifications may be made without deviating from the scope of the invention. Accordingly, the invention is not limited except as by the appended claims.

1. A method comprising:
providing a crystalline substrate including a growth surface having a set of lattice parameters; and
growing, on the growth surface, a solid hydride material,
wherein the set of lattice parameters impart a strain to the solid hydride material that reduces an applied pressure at which the solid hydride material exhibits superconductivity.

2. The method of claim 1, wherein providing the crystalline substrate comprises growing a diamond structure by chemical vapor deposition.

3. The method of claim 2, wherein the growth surface is parallel to a (110) lattice plane or a (121) lattice plane of the diamond structure.

4. The method of claim 2, wherein providing the crystalline substrate further comprises replacing carbon atoms of the grown diamond structure by substitutional doping with boron (B), sulfur (S), phosphorus (P), Hydrogen Sulfide (H₂S), or a combination thereof.

5. The method of claim 4, wherein the substitutional doping comprises focused ion beam deposition of B, S, P, H₂S, or a combination thereof.

6. The method of claim 1, wherein growing the solid hydride material comprises depositing, via molecular-beam epitaxy, constituents thereof.

7. The method of claim 1, wherein growing the solid hydride material comprises depositing, via molecular-beam epitaxy, constituents thereof in stoichiometric amounts.

8. The method of claim 1, wherein growing the solid hydride material comprises depositing, via molecular-beam epitaxy, constituents thereof in non-stoichiometric amounts.

9. The method of claim 1, wherein the solid hydride material comprises a host-guest structure.

10. The method of claim 9, wherein a guest component of the host-guest structure includes a sulfur hydride, a carbon hydride, or a combination thereof.

11. The method of claim 9, wherein a host component of the host-guest structure includes lithium (Li), boron (B), beryllium (Be), magnesium (Mg), manganese (Mn), iron (Fe), scandium (Sc), nitrogen (N), selenium (Se), phosphorous (P), yttrium (Y), carbon (C), sulfur (S), lanthanum (La), or a combination thereof.

12. (canceled)

13. The method of claim 1, wherein:
the solid hydride material exhibits superconductivity, absent the strain, at a first combination of a first temperature and a first pressure; and
the solid hydride material exhibits superconductivity, due to the strain, at a second combination of a second temperature and a second pressure, wherein the second temperature is higher than the first temperature, the second pressure is lower than the first pressure, or both.

14. The method of claim 1, wherein the solid hydride material has an Im-3 m cubic or Cmcm orthorhombic crystal structure.

15. The method of claim 14, wherein the set of lattice parameters of the growth surface are symmetrical with the crystal structure of the solid hydride material.

16. The method of claim 1, wherein the strain reduces an inter-atomic spacing in the solid hydride material.

17. The method of claim 16, wherein the inter-atomic spacing is an inter-hydrogen spacing.

18. The method of claim 17, wherein the inter-hydrogen spacing is between 1.1 Å and 1.3 Å.

19. The method of claim 1, wherein the solid hydride material comprises a component covalently bonded to hydrogen and having a coordination number of at least 6.

20. The method of claim 1, wherein the solid hydride material comprises a covalent metal hydride.

21. The method of claim 1, wherein the solid hydride material has a hydrogen content that is higher compared to a largest content possible as determined by formal oxidation states of constituent elements of the solid at ambient conditions absent the strain.

22. A superconducting structure made by a method according to claim 1.

23-40. (canceled)

41. A method for making superconductive material, the method comprising:
using the superconducting structure of claim 22 to provide a substrate;
depositing constituents of a solid hydride material on the superconducting structure using chemical vapor deposition.

42. A quantum computing apparatus comprising the superconducting structure claim 22.
